(19) United States
(12) Patent Application Publication
(10) Pub. No.: US 2015/0024242 A1
(43) Pub. Date: Jan. 22, 2015

(54) BATTERY MONITORING DEVICE AND A BATTERY UNIT

(71) Applicant: Toyota Jidosha Kabushiki Kaisha, Toyota-shi (JP)

(72) Inventor: Norio Nishiwaki, Tajimi-shi (JP)

(21) Appl. No.: 14/328,874

(22) Filed: Jul. 11, 2014

(30) Foreign Application Priority Data
Jul. 18, 2013 (JP) 2013-149753

(51) Int. Cl. H01M 10/48; G01R 31/36

(52) U.S. Cl. CPC H01M 10/48; G01R 31/3627; H01M 2220/20
USPC 429/90; 324/426

(57) ABSTRACT

A battery monitoring device includes a first unit arranged outside a plurality of stacks each of which includes cells; a plurality of second units arranged in each of the stacks to output voltage data of the cells; a signal line that connects the second units and the first unit in a daisy chain mode; and a detection unit that detects a stack voltage wherein the first unit determines that a disconnection is generated on the signal line when a response is not received from the plurality of second units via the signal line after sending data is sent to the plurality of second units via the signal line and, determines on which path of the signal line, a forward path or a backward path, the disconnection is generated based on a difference between the stack voltage and a total of all detected output voltages sent from the second units.

### INCORPORATION BY REFERENCE

The disclosure of Japanese Patent Application No. 2013-149753 filed on Jul. 18, 2013 including the specification, drawings and abstract is incorporated herein by reference in its entirety.

### BACKGROUND OF THE INVENTION

1. Field of the Invention

The present invention relates to a battery monitoring device and a battery unit.

2. Description of Related Art

A device is developed that monitors the status of a plurality of assembled batteries using a plurality of ICs interconnected by a signal line. For example, a main microcomputer arranged in a circuit, the voltage of which is lower than that of assembled batteries, outputs a voltage detection command. In response to this command, the first to fifth voltage-monitoring ICs, arranged in the assembled batteries, send the measured voltage data on the corresponding battery cells to the main microcomputer for monitoring the status of the plurality of assembled batteries (for example, see Japanese Patent Application Publication No. 2011-050176 (JP 2011-050176 A)).

The main microcomputer checks if the number of received battery-cell digital voltage signals is equal to the number of the first to fifth voltage monitoring ICs on the communication line to determine whether the received data is normal reception data.

The problem with the status monitoring unit of a plurality of assembled batteries described above is that it cannot be determined on which communication line path, forward path (upstream communication line) or backward path (downstream communication line), a communication abnormality is generated.

### SUMMARY OF THE INVENTION

The present invention provides a battery monitoring device and a battery unit capable of determining on which communication line path, forward path or backward path, an abnormality is generated.

A battery monitoring device in a first aspect of the present invention includes a first control unit arranged outside a plurality of battery stacks each of which includes battery cells; a plurality of second control units arranged in each of the plurality of battery stacks to detect an output voltage of the battery cells and then output voltage data indicating the output voltage; a signal line that connects the plurality of second control units and the first control unit in a daisy chain mode; and a stack voltage detection unit that detects a stack voltage that is a total voltage of the plurality of battery cells included in the battery stacks wherein each of the second control units receives a data signal sent from the first control unit via the signal line and, in response to the data signal, sends a response signal and the first control unit determines that a disconnection is generated on the signal line when the response signal is not received via the signal line within a predetermined period after the data signal is sent to the plurality of second control units via the signal line and, in addition, determines on which path of the signal line, a forward path or a backward path, the disconnection is generated based on a difference between the stack voltage and a total of output voltages, the stack voltage detected by the stack voltage detection unit, the total of output voltages indicated by the voltage data received from the second control units via the signal line.

A battery monitoring device in a second aspect of the present invention includes a first control unit arranged outside a plurality of battery stacks each of which includes battery cells; a plurality of second control units arranged in each of the plurality of battery stacks to detect an output voltage of the battery cells and then output voltage data indicating the detected voltage; a signal line that connects the plurality of second control units and the first control unit in a daisy chain mode; and a current detection unit provided between each two of the plurality of second control units in a forward path section of the signal line wherein each of the second control units receives a data signal sent from the first control unit via the signal line and, in response to the data signal, sends a response signal and the first control unit determines that a disconnection is generated on the signal line when no response is received from the plurality of second control units via the signal line within a predetermined period after the data signal is sent to the plurality of second control units via the signal line and, in addition, determines on which path of the signal line, a forward path or a backward path, the disconnection is generated based on a detection result of the current detection unit.

A battery monitoring device in a third aspect of the present invention includes a first control unit arranged outside a plurality of battery stacks each of which includes battery cells; a plurality of second control units arranged in each of the plurality of battery stacks to detect an output voltage of the battery cells and then output voltage data indicating the output voltage; a signal line that connects the plurality of second control units and the first control unit in a daisy chain mode; and a communication line that connects a second control unit farthest from the first control unit and the first control unit wherein each of the second control units receives a data signal sent from the first control unit via the signal line and, in response to the data signal, sends a response signal and the first control unit determines that a disconnection is generated on the signal line when no response is received from the plurality of second control units via the signal line within a predetermined period after the data signal is sent to the plurality of second control units via the signal line and at the same time and the first control unit determines that the disconnection is generated on a backward path of the signal line when sending data is received from the second control unit farthest from the first control unit via the communication line and determines that the disconnection is generated on a forward path of the signal line when sending data is not received from the second control unit via the communication line.

A battery unit in a fourth aspect of the present invention includes a plurality of battery stacks each of which includes battery cells; a first control unit arranged outside the plurality of battery stacks; a plurality of second control units arranged in each of the plurality of battery stacks to detect an output voltage of the battery cells and then output voltage data indicating the output voltage; a signal line that connects the plurality of second control units and the first control unit in a daisy chain mode; and a stack voltage detection unit that detects a stack voltage that is a total voltage of the plurality of battery cells included in the battery stacks wherein each of the second control units receives a data signal sent from the first control unit via the signal line and, in response to the data signal, sends a response signal and the first control unit determines that a disconnection is generated on the signal line when the response signal is not received via the signal line within a predetermined period after the data signal is sent to the plurality of second control units via the signal line and, in addition, determines on which path of the signal line, a forward path or a backward path, the disconnection is generated based on a difference between the stack voltage and a total of output voltages, the stack voltage detected by the stack voltage detection unit, the total of output voltages indicated by the voltage data received from the second control units via the signal line.

A battery unit in a fifth aspect of the present invention includes a plurality of battery stacks each of which includes battery cells; a first control unit arranged outside the plurality of battery stacks; a plurality of second control units arranged in each of the plurality of battery stacks to detect an output voltage of the battery cells and then output voltage data indicating the detected voltage; a signal line that connects the plurality of second control units and the first control unit in a daisy chain mode; and a current detection unit provided between each two of the plurality of second control units in a forward path section of the signal line wherein each of the second control units receives a data signal sent from the first control unit via the signal line and, in response to the data signal, sends a response signal and the first control unit determines that a disconnection is generated on the signal line when no response is received from the plurality of second control units via the signal line within a predetermined period after the data signal is sent to the plurality of second control units via the signal line and, in addition, determines on which path of the signal line, a forward path or a backward path, the disconnection is generated based on a detection result of the current detection unit.

A battery unit in a sixth aspect of the present invention includes a plurality of battery stacks each of which includes battery cells; a first control unit arranged outside the plurality of battery stacks; a plurality of second control units arranged in each of the plurality of battery stacks to detect an output voltage of the battery cells and then output voltage data indicating the output voltage; a signal line that connects the plurality of second control units and the first control unit in a daisy chain mode; and a communication line that connects a second control unit farthest from the first control unit and the first control unit wherein each of the second control units receives a data signal sent from the first control unit via the signal line and, in response to the data signal, sends a response signal and the first control unit determines that a disconnection is generated on the signal line when no response is received from the plurality of second control units via the signal line within a predetermined period after the data signal is sent to the plurality of second control units via the signal line and at the same time the first control unit determines that the disconnection is generated on a backward path of the signal line when sending data is received from the second control unit farthest from the first control unit via the communication line and determines that the disconnection is generated on a forward path of the signal line when sending data is not received from the second control unit via the communication line.

According to the aspects described above, it is possible to determine on which communication line path, forward path or backward path, an abnormality is generated.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a diagram showing a battery monitoring device and a battery unit in a first embodiment of the present invention;

FIG. 2A is a diagram schematically showing the battery monitoring device in the first embodiment;

FIG. 2B is a diagram showing the configuration of the IC chip in the first embodiment;

FIG. 3 is a diagram showing a data flow among an ECU and IC1-IC4 in the battery monitoring device in the first embodiment;

FIG. 4 is a diagram showing a voltage data sending path in the battery monitoring device in another example in the first embodiment;

FIGS. 5A and 5B are diagrams showing a data transfer status when a disconnection is generated on a signal line between IC4 and IC3;

FIG. 6 is a flowchart showing the processing content of the ECU when a disconnection is generated on the signal line of the battery monitoring device in the first embodiment;

FIG. 7 is a diagram showing the data transfer path in the test mode of the battery monitoring device in the first embodiment;

FIG. 8 is a diagram showing the data transfer path in the recovery mode of the battery monitoring device in the first embodiment;

FIG. 9 is a diagram showing a communication circuit of a battery monitoring device in a second embodiment of the present invention;

FIG. 10A is a diagram schematically showing a battery monitoring device in a third embodiment of the present invention; and

FIG. 10B is a diagram showing the configuration of the IC chip in the third embodiment.

### DETAILED DESCRIPTION OF EMBODIMENTS

Embodiments of a battery monitoring device and a battery unit of the present invention are described below.

### First Embodiment

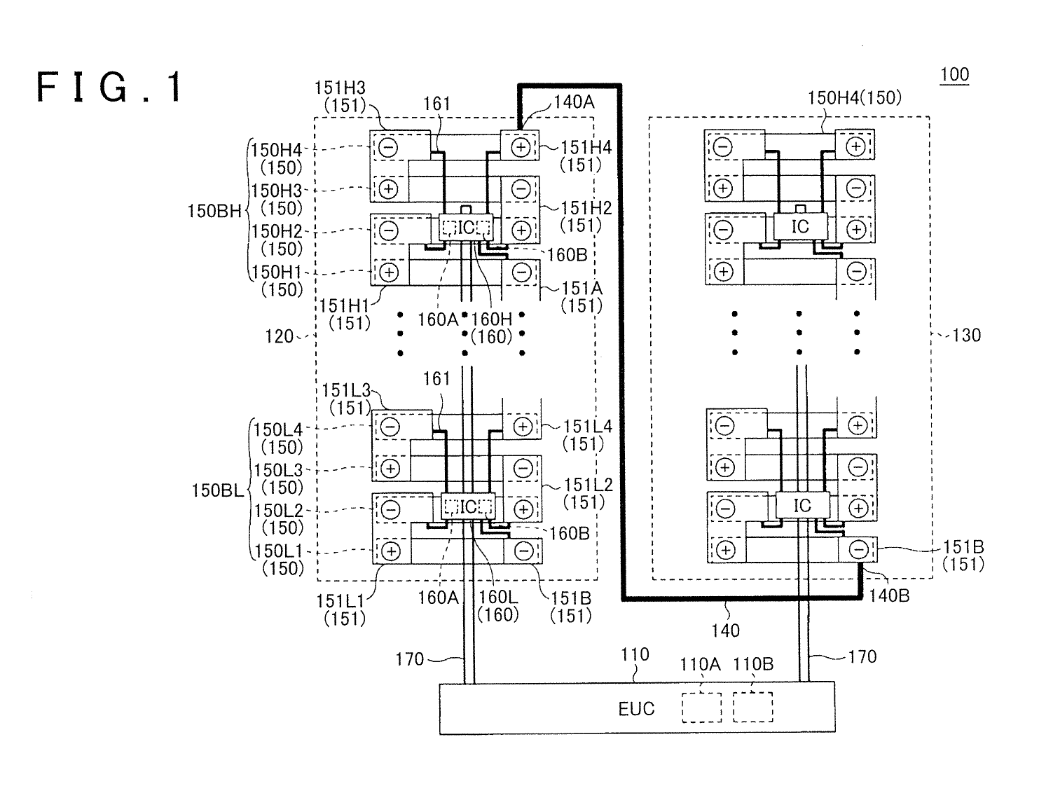

FIG. 1 is a diagram showing a battery monitoring device and a battery unit in a first embodiment.

The main components of a battery unit 100 in the first embodiment include an electronic control unit (ECU) 110 and stacks 120 and 130. Each of the stacks 120 and 130 includes a plurality of cells 150 and integrated circuit (IC) chips 160. The battery monitoring device in the first embodiment includes the ECU 110 and the IC chips 160 included in the stacks 120 and 130.

FIG. 1 schematically shows an example of the arrangement of the battery unit 100 in planar view. The arrangement of the ECU 110 and stacks 120 and 130 is not limited to the pattern shown in FIG. 1 but may be an arrangement of another pattern.

The battery unit 100 is a device used as a power supply from which electric power is output for driving the drive device of an electric vehicle. The drive device of an electric vehicle refers to a device that drives a vehicle by driving a drive motor using electric power supplied from the battery unit 100.

An electric vehicle may use any system or may have any configuration if it can travel by driving a drive motor using electric power. Typically, an electric vehicle includes the following two types of vehicle: one is a hybrid vehicle (HV) that uses both an engine and a traveling motor as the power source and the other is an electric vehicle (EV) that uses only a traveling motor as the power source.

The ECU 110, a control device that performs the voltage control processing for the stacks 120 and 130 of the battery unit 100, is an example of a first control unit. The ECU 110 includes a voltage control unit 110A and a memory 110B.

The memory 110B is a nonvolatile memory to and from which data can be written and read. The ECU 110 may further include an authentication unit that performs the authentication processing for the stacks 120 and 130.

The voltage control processing performed by the ECU 110 will be described later. The following mainly describes the physical configuration of the ECU 110 and the stacks 120 and 130 with reference to FIG. 1.

The stacks 120 and 130, similar in configuration, are connected in series via a cable 140. Therefore, the configuration of only the stack 120 is described in detail below.

The stack 120 includes a plurality of cells 150 and a plurality of IC chips 160. FIG. 1 shows eight cells 150H1, 150H2, 150H3, 150H4, 150L1, 150L2, 150L3, and 150L4 that are included in the plurality of cells 150, and positioned at the top end and the bottom end, of the stack 120.

In the description below, when the cells 150H1, 150H2, 150H3, 150H4, 150L1, 150L2, 150L3, and 150L4 are not distinguished from the cells 150 (not shown) between the cell 150L4 and cell 150H1, the cells are called simply as a cell 150.

The symbols “+” and “−” in each cell 150 indicate the positions of the positive terminal and the negative terminal. The plurality of cells 150 included in the stack 120 is connected in series via connection parts 151.

The cells 150H1, 150H2, 150H3, and 150H4 are connected in series via the connection parts 151H1, 151H2, and 151H3. The positive terminal (+) of the cell 150H4 is connected to one end 140A of the cable 140 via the connection part 151H4, and the negative terminal (−) of the cell 150H1 is connected to the connection part 151A.

Similarly, the cells 150L1, 150L2, 150L3, and 150L4 are connected in series via the connection parts 151L1, 151L2, and 15113. The positive terminal (+) of the cell 150L4 is connected to the negative terminal (−) of a cell 150, not shown, via a connection part 151L4, and the negative terminal (−) of the cell 150L1 is connected to the connection part 151B.

In the description below, when the connection parts 151A, 151H1, 151H2, 151H3, and 151H4 and the connection parts 151B, 151L1, 151L2, 151L3, and 151L4 are not distinguished among them, the connection parts are called simply the connection part 151.

A plurality of cells 150 (not shown) between the cell 150L4 and the cell 150H1 are connected in series via the connection parts 151 not shown. In this manner, the plurality of cells 150 included in the stack 120 is connected in series via the connection parts 151.

Therefore, of the plurality of cells 150 included in the stack 120, the highest-potential cell is the cell 150H4 and the lowest-potential cell is the cell 150L1.

Each cell 150, such as a lithium ion secondary battery, is a secondary battery in which lithium ions in the electrolyte conduct electricity. In the description below, a lithium ion secondary battery is called a lithium ion battery. A protection circuit should be provided on a lithium ion battery, which is sensitive to overcharge or over-discharge, to protect it from an overcharge, over-discharge, and overcurrent condition. The ECU 110 and the IC chip 160 work together to protect the cell 150 from an overcharge, over-discharge, and overcurrent condition.

The IC chips 160 are configured to manage the cells 150 in the stack 120, four cells 150 by each IC chip 160. FIG. 1 shows an IC chip 160H that connects to the cells 150H1, 150H2, 150H3, and 150H4, and an IC chip 160L that connects to the cells 150L1, 150L2, 150L3, and 150L4.

For a plurality of cells 150 between the cell 150L4 and the cell 150H1, one IC chip 160, not shown, is connected to each four cells 150. That is, the stack 120 includes a multiple of four cells 150 with one IC chip 160 connected to each four cells 150.

The four cells 150 connected to one IC chip 160 is called a block 150B. That is, the cells 150H1, 150H2, 150H3, and 150H4 configure a block 150BH, and the cells 150L1, 150L2, 150L3, and 150L4 configure a block 150BL.

A plurality of IC chips 160 (including the IC chips 160H and 160L) included in the stack 120 is called simply the IC chip 160 when they are not distinguished among them. Each IC chip 160 is an example of a second control unit.

The IC chip 160H is connected to the connection parts 151A, 151H1, 151H2, 151H3, and 151H4 via five cables 161. The IC chip 160H detects the end-to-end voltage each of the cells 150H1, 150H2, 150H3, and 150H4 via the five cables 161.

Similarly, the IC chip 160L is connected to the connection parts 151B, 151L1, 151L2, 151L3, and 151L4 via five cables 161. The IC chip 160L detects the end-to-end voltage of each of the cells 150L1, 150L2, 150L3, and 150L4 via the five cables 161.

Each IC chip 160 is connected to the ECU 110 in a loop via a signal line 170. When the voltage control processing is performed, the ECU 110 transmits data via the signal line 170.

The signal line 170 shown in FIG. 1 is connected in a loop among the ECU 110 and the IC chips 160. The signal line 170, which loops back at the IC chip 160H, forms a daisy chain. The signal line 170 is connected so that data, which is transmitted from the ECU 110 to the IC chips 160, is transmitted sequentially to the IC chips 160 and is returned to the ECU 110.

That is, data that is sent from the ECU 110 to the IC chips 160 and then from the IC chips 160 to the ECU 110 is transmitted as follows. When sent from the ECU 110 to the IC chips 160, data is transmitted from the ECU 110, through the IC chip 160L and then sequentially through the other IC chips, to the IC chip 160H via one of the two signal lines 170 (for example, signal line on the right side). When sent from the IC chips 160 to the ECU 110, data is transmitted from the IC chip 160H, sequentially through the other IC chips and then through the IC chip 160L, to the ECU 110 via the other of the two signal lines 170 (for example, signal line on the left side). In this way, the signal line 170 is connected in a loop among the ECU 110 and the IC chips 160 to form a daisy chain.

Although the stack 120 has been described above, the stack 130 has a configuration similar to that of the stack 120. In FIG. 1, only some of the reference numerals are shown in the stack 130 for easy understanding.

A connection part 151B of the stack 130 is connected to the other end 140B of the cable 140. This means that the plurality of cells 150 included in the stack 120 and the plurality of cells 150 included in the stack 130 are connected all in series.

Of these cells 150, the highest-potential cell is the cell 150H4 in the stack 130 and the lowest-potential cell is the cell 150L1 in the stack 120.

Although two stacks, 120 and 130, are connected in series in FIG. 1, more stacks may be connected in series or only one stack (for example, stack 120 only) may be used. Although connected in series in FIG. 1, the stacks 120 and 130 may be connected in parallel.

In the battery unit 100 described above, each IC chip 160 detects the end-to-end voltages of the four cells 150. The data indicating the average of the detected end-to-end voltages of the four cells 150 is transmitted to the ECU 110.

Based on the data indicating the end-to-end voltage transmitted from each of the IC chips 160, the ECU 110 causes the IC chip 160 to discharge the cell 150, which is included in the cells 150 in the stacks 120 or 130 and the voltage of which is equal to or higher than a predetermined voltage, to adjust the output voltage of the cells 150 included in the stacks 120 and 130.

To adjust the output voltage, a discharge path resistor is provided externally to the IC chip 160. The both terminals of the cell 150, the output voltage of which is equal to or higher than the predetermined voltage, are connected to the discharge path resistor external to the IC chip 160 to conduct the output current of the cell 150 to the discharge path resistor.

The output voltage of the cell 150 is synonymous with the end-to-end voltage or the charging voltage of the cell 150.

In the battery unit 100 in the first embodiment, the ECU 110 performs the voltage control processing for the stacks 120 and 130 of the battery unit 100 to adjust the output voltage of the cells 150 included in the stacks 120 and 130. The voltage control processing is performed by the voltage control unit 110A of the ECU 110.

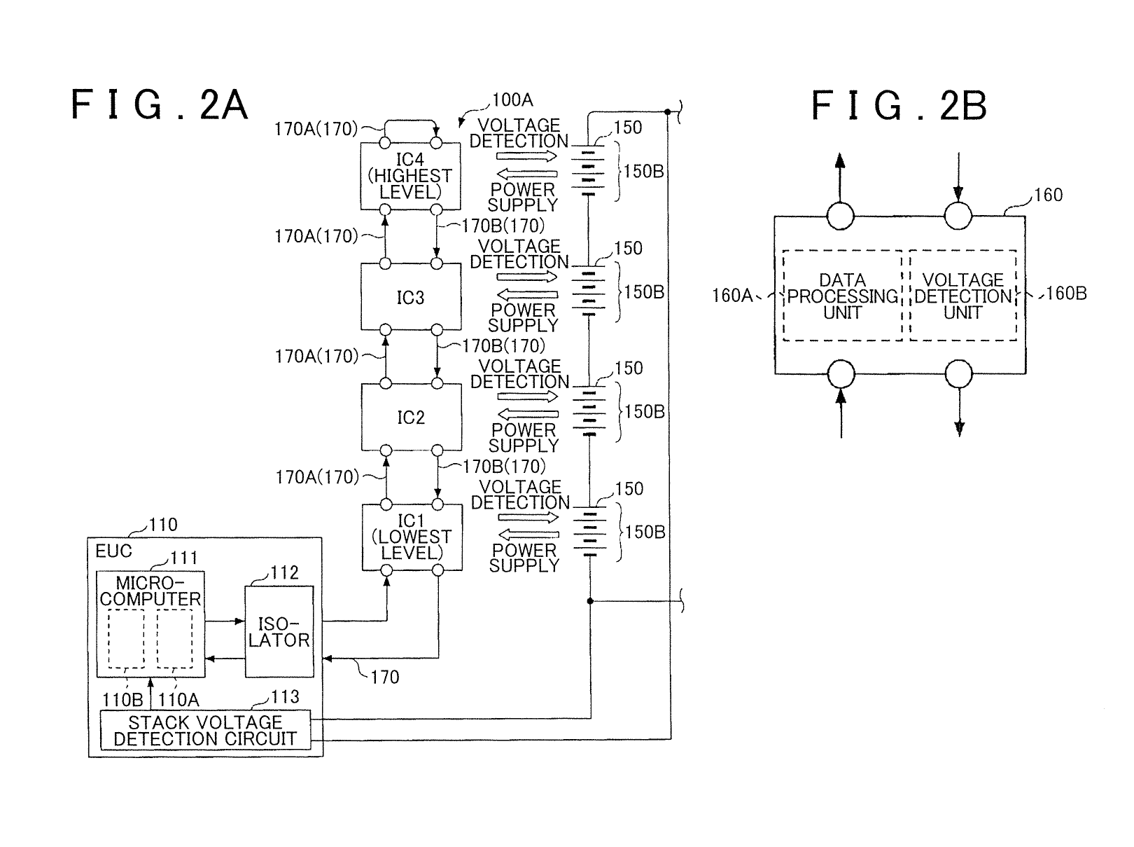

Next, a battery monitoring device 100A in the first embodiment is described with reference to FIG. 2.

FIG. 2 is a diagram showing the battery monitoring device 100A in the first embodiment. FIG. 2A is a diagram schematically showing the battery monitoring device 100A, and FIG. 2B is a diagram showing the configuration of the IC chip 160.

FIG. 2A shows the components of the battery monitoring device 100A: the ECU 110 and IC1-IC4. IC1-IC4 each correspond to the IC chip 160 shown in FIG. 1. FIG. 2A also shows the components of the ECU 110: a microcomputer 111, an isolator 112, and a stack voltage detection circuit 113. The voltage control unit 110A and the memory 110B are included in the microcomputer 111.

IC1-IC4 and the ECU 110 are networked in the daisy chain mode via the signal line 170. The communication line of a network in the daisy chain mode is composed of a forward path communication line and a backward path communication line. In a network in the daisy chain mode, a plurality of control devices (ECU and IC1-IC4) is connected to the forward path communication line and the backward path communication line. In the description below, the whole network connected in the daisy chain mode is sometimes called simply a daisy chain. On the signal line 170, signals are transferred in the direction indicated by the arrow.

In FIG. 2, the signal line 170 is divided into two for the sake of description: a signal line 170A corresponding to the forward path of the daisy chain and a signal line 170B corresponding to the backward path of the daisy chain. The forward path signal line 170A originates from the ECU 110 and extends in the direction of IC1-IC4. Note that the signal line 170 originating from IC4 and returning to IC4 is a part of the forward path signal line 170A.

The backward path signal line 170B is a signal line that originates from IC4 and extends in the direction of the ECU 110. When not distinguished, the forward path signal line 170A and the backward path signal line 170B are called simply the signal line 170.

IC4, the IC farthest from the ECU 110, is the highest-level IC chip 160 (see FIG. 1) and IC1, the IC nearest to the ECU 110, is the lowest-level IC chip (160).

IC1-IC4, all with the same configuration, each have four input terminals and four output terminals. In FIG. 2A, the input terminals and the output terminals of IC1-IC4 are indicated by a circle (∘).

In each of IC1-IC4, the bottom-left terminal and the top-right terminal, to which the arrow-shaped signal line 170 points, are input terminals. In each of IC1-IC4, the bottom-right terminal and the top-left terminal, from which the arrow-shaped signal line 170 originates, are output terminals.

The bottom-left input terminal and the bottom-right output terminal of the lowest-level IC1 are connected to the ECU 110 via the signal line 170. IC1 is configured to recognize that it is the lowest-level IC chip 160, for example, by pulling up the terminal, not shown, to the power supply VCC.

The top-left output terminal and the top-right input terminal of the highest-level IC4 are connected in a loop by the signal line 170. This allows IC4 to recognize that it is the highest-level IC chip 160.

As described above, IC1 is connected to the ECU 110 by the signal line 170, and IC1-IC4 are connected by the signal line 170.

The signal line 170 connects IC1-IC4 and the ECU 110 in the daisy chain mode.

Each of IC1-IC4 detects the output voltages of the four cells 150 included in the corresponding block 150B and calculates the average of the four output voltages. Each of IC1-IC4 sends the voltage data, which indicates the average of the four output voltages, to the ECU 110 via the signal line 170.

As shown in FIG. 2B, the IC chip 160 has a configuration that has a data processing unit 160A and a voltage detection unit 160B. When a voltage detection command is received, the data processing unit 160A causes the voltage detection unit 160B to calculate the average of the output voltages of the four cells 150 included in the block 150B and, based on the average of the output voltages, generates voltage data. In addition, the data processing unit 160A transfers the voltage detection command, sent from the ECU 110, and voltage data sent from the other ICs.

The stack voltage detection circuit 113 is a circuit that detects the total value (stack voltage) of the output voltages of a total or 16 cells 150 that are included in the four blocks 150B (four cells 150 in each block 150B) included in the stack 120 or 130 (see FIG. 1).

Data, which indicates the stack voltage detected by the stack voltage detection circuit 113, is input to the voltage control unit 110A of the microcomputer 111. The stack voltage is used by the ECU 110 to determine on which path of the signal line 170, forward path signal line 170A or backward path signal line 170B, a disconnection is generated.

The stack voltage detection circuit 113, a circuit capable of detecting the end-to-end voltages of the 16 cells 150 connected in series, includes a resistor with a predetermined resistance value and outputs the voltage signal, which indicates the end-to-end voltage, to the microcomputer 111. The stack voltage detection circuit 113 detects a voltage on a stack (120, 130) basis. Therefore, the stack voltage detection circuit 113 is configured to detect the stack voltage of the stack 120 and the stack 130.

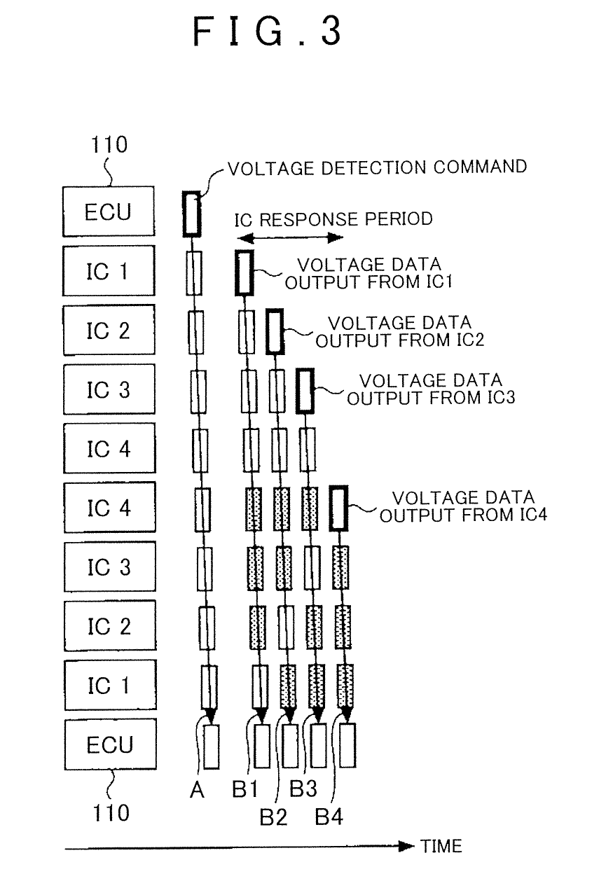

Next, the data flow among the ECU 110 and IC1-IC4 is described below with reference to FIG. 3.

FIG. 3 is a diagram showing the data flow among the ECU 110 and IC1-IC4 in the battery monitoring device 100A in the first embodiment. In FIG. 3, the horizontal axis is a time axis.

In the battery monitoring device 100A in the first embodiment, the voltage detection command is sent sequentially from the ECU 110 to each of IC1-IC4. After that, each of IC4, IC3, IC2, and IC1 sends voltage data, which indicates the average voltage value of the four cells 150 corresponding to that IC, to the ECU 110.

In FIG. 3, the blocks of the ECU, IC1, IC2, IC3, IC4, IC4, IC3, IC2, IC1, and ECU are shown to indicate the flow of the voltage detection command and voltage data vertically from top to bottom. On the right side of each block, the voltage detection command received by, and the voltage data output from, the block are shown.

The voltage detection command and the voltage data shown in FIG. 3 are shifted to the right as it goes from top to bottom to indicate the passage of time.

As shown in FIG. 3, the voltage detection command is transferred sequentially from the ECU 110 to IC1-IC4 as indicated by arrow A. IC1-IC4 sequentially receive the voltage detection command.

After reaching IC4, the voltage detection command is sequentially transferred again in the order of IC4, IC3, IC2, IC1, and ECU 110 via the signal line 170 (see FIG. 1 and FIG. 2). In this way, the voltage detection command returns to the ECU 110. The voltage detection command, which is output by the ECU 110 to the signal line 170 (see FIG. 1 and FIG. 2) at the starting point of arrow A, is indicated by the thick-bordered box.

The ECU 110 sequentially sends the voltage detection command to IC1-IC4. This voltage detection command causes IC1-IC4 to send voltage data, which indicates the average of the output voltages of the four cells 150, to the ECU 110.

The processing, in which the ECU 110 sequentially sends the voltage detection command to IC1-IC4, has the following meaning.

That is, the ECU 110 outputs the voltage detection command to the signal line 170 that configures a daisy chain. The voltage detection command is sequentially received in turn by IC1-IC4. IC1-IC4 sequentially send voltage data to the ECU 110 as shown in FIG. 3.

In the first embodiment, data or an instruction is transferred among IC1-IC4 over the daisy chain, configured by the signal line 170, as follows. That is, data or an instruction is transferred from IC1 to higher levels IC2, IC3, and IC4, looped back at IC4, and then transferred from IC4 to lower levels IC3, IC2, and IC1.

Therefore, when the voltage detection command is received from the ECU 110, IC1 sends voltage data or the voltage detection command to IC2. When voltage data or the voltage detection command is received from the IC1, IC2 sends voltage data or the voltage detection command to IC3. When voltage data or the voltage detection command is received from IC2, IC3 sends voltage data or the voltage detection command to IC4.

When voltage data or the voltage detection command is received from the IC3, IC4 loops back and sends voltage data or the voltage detection command to IC3. When voltage data or the voltage detection command is received from the IC4, IC3 sends voltage data or the voltage detection command to IC2. When voltage data or the voltage detection command is received from IC3, IC2 sends voltage data or the voltage detection command to IC1. When voltage data or the voltage detection command is received from IC2, IC1 sends voltage data or the voltage detection command to the ECU 110.

More specifically, the processing described above is performed as follows. When IC1 receives the voltage detection command and finds that its turn has come, it creates voltage data, which represents the average of the output voltages of the four corresponding cells 150, and sends the created voltage data to the next higher level, IC2.

When IC2 receives the voltage detection command and finds that its turn has come, it creates voltage data, which represents the average of the output voltages of the four corresponding cells 150, and sends the created voltage data to the next higher level, IC3.

When IC3 receives the voltage detection command and finds that its turn has come, it creates voltage data, which represents the average of the output voltages of the four corresponding cells 150, and sends the created voltage data to the next higher level, IC4.

When IC4 receives the voltage detection command and finds that its turn has come, it creates voltage data, which represents the average of the output voltages of the four corresponding cells 150, and sends the created voltage data to IC3.

In FIG. 3, voltage data, which is output to the signal line 170 (see FIG. 1 and FIG. 2) by IC4, IC3, IC2, and IC1, is indicated by a thick-bordered box.

When the voltage detection command is received, IC1, IC2, IC3, and IC4 send voltage data, sequentially beginning with IC1, to their higher levels, IC2, IC3, and IC4, via the signal line 170 as shown in FIG. 3.

That is, first, IC1 that is on the lowest level sends the voltage data on its four corresponding cells 150 to its higher levels, IC2, IC3, and IC4, as shown by arrow B1, via the signal line 170. After that, the voltage data travels from IC4 and reaches the ECU 110 through IC3, IC2, and IC1 again via the signal line 170.

Next, IC2 that is one level higher than IC1 sends the voltage data on its four corresponding cells 150 to its higher levels, IC3 and IC4, as shown by arrow B2, via the signal line 170. After that, the voltage data travels from IC4 and reaches the ECU 110 through IC3, IC2, and IC1 again via the signal line 170.

Next, IC3 that is one level higher than IC2 sends the voltage data on its four corresponding cells 150 to its higher level, IC4, as shown by arrow B3, via the signal line 170. After that, the voltage data travels from IC4 and reaches the ECU 110 through IC3, IC2, and IC1 again via the signal line 170.

Lastly, IC4 that is on the highest level sends the voltage data on its four corresponding cells 150 to IC3, as shown by arrow B4, via the signal line 170. After that, the voltage data reaches the ECU 110 through IC3, IC2, and IC1.

After the voltage data, transferred on the daisy chain configured by the signal line 170, is looped back at IC4, each of IC1-IC4 acquires voltage data on the ICs other than itself.

More specifically, IC4 acquires voltage data on IC1-IC3 indicated in gray in FIG. 3. That is, after the loopback at IC4 on the daisy chain, IC4 acquires the voltage data on IC1-IC3.

IC3 acquires voltage data on IC1, IC2, and IC4 indicated in gray in FIG. 3. That is, after the loopback at IC4 on the daisy chain, IC3 acquires voltage data on IC1, IC2, and IC4.

IC2 acquires voltage data on IC1, IC3, and IC4 indicated in gray in FIG. 3. That is, after the loopback at IC4 on the daisy chain, IC2 acquires voltage data on IC1, IC3, and IC4.

IC1 acquires voltage data on IC2, IC3, and IC4 indicated in gray in FIG. 3. That is, after the loopback at IC4 on the daisy chain, IC1 acquires voltage data on IC2, IC3, and IC4.

As described above, according to the battery monitoring device 100A in the first embodiment, a higher level IC can obtain voltage data on the lower level ICs. This is because each of the ICs sequentially sends the voltage data on its four corresponding cells 150 to the ICs on its higher-level side via the signal line 170, as described above, beginning with IC1 on the lowest level.

That is, because IC1, IC2, and IC3 output voltage data to the ICs on the higher-level side via the signal line 170, each of IC1-IC4 can obtain voltage data on all IC1-IC4 after the voltage data transmitted on the signal line 170 is looped back at IC4.

This enables all IC1-IC4 to calculate the average of voltage values using voltage data on all IC1-IC4.

Therefore, the first embodiment provides the battery monitoring device 100A and the battery unit 100 that can control the voltage efficiently.

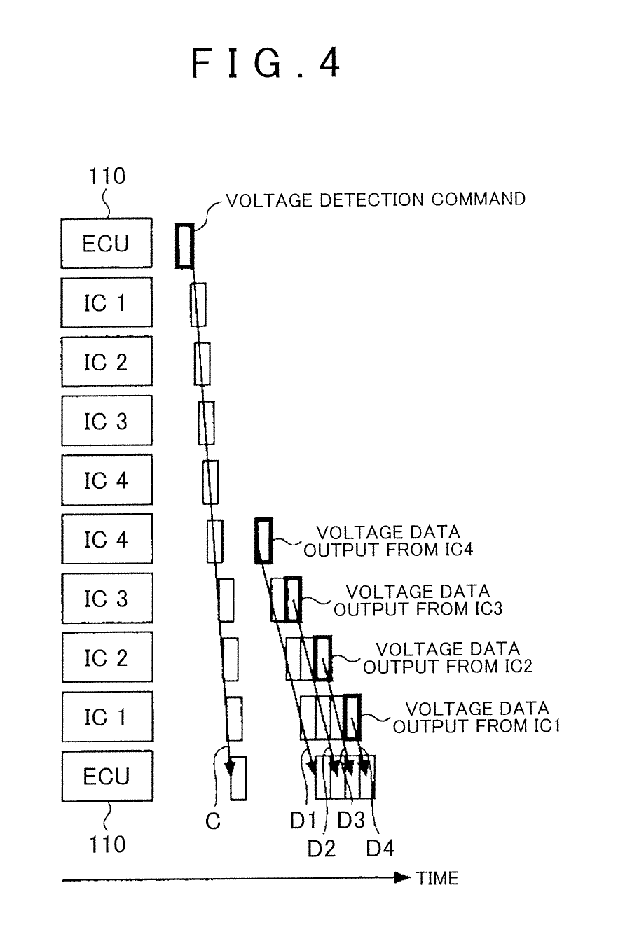

The voltage data sending path in the battery monitoring device 100A may also be the one shown in FIG. 4.

FIG. 4 is a diagram showing a voltage data sending path in the battery monitoring device 100A in another example in the first embodiment.

In FIG. 4, the voltage detection command is sent sequentially from the ECU 110 to each of IC1-IC4. After that, each of IC4, IC3, IC2, and IC1 sends voltage data, which indicates the voltage of the cells 150, to the ECU 110.

As shown in FIG. 4, the voltage detection command is transferred sequentially from the ECU to IC1-IC4 as indicated by arrow C. IC1-IC4 sequentially receive the voltage detection command.

After the voltage detection command reaches IC4, it is transferred again sequentially to IC4, IC3, IC2, IC1, and ECU 110 via the signal line 170 (see FIG. 1 and FIG. 2).

When the voltage detection command is received, each of IC4, IC3, IC2, and IC1 sends voltage data, which indicates the output voltages of the cells 150 monitored by the IC, to the ECU 110. In FIG. 4, voltage data, which is output to the signal line 170 (see FIG. 1 and FIG. 2) by IC4, IC3, IC2, and IC1, is indicated by a thick-bordered box.

As a result, voltage data output from IC4 reaches the ECU 110 through IC3, IC2, and IC1 as indicated by arrow D1. Voltage data output from IC3 reaches the ECU 110 through IC2 and IC1 as indicated by arrow D2.

Voltage data output from IC2 reaches the ECU 110 through IC1 as indicated by arrow D3. Voltage data output from IC1 reaches the ECU 110 as indicated by arrow D4.

That is, IC3 can obtain voltage data on IC4, IC2 can obtain voltage data on IC4 and IC3, and IC1 can obtain voltage data on IC4, IC3, and IC2.

The battery monitoring device 100A may use the transfer method shown in FIG. 4 though the transfer method shown in FIG. 3 can control the voltage more efficiently than that shown in FIG. 4.

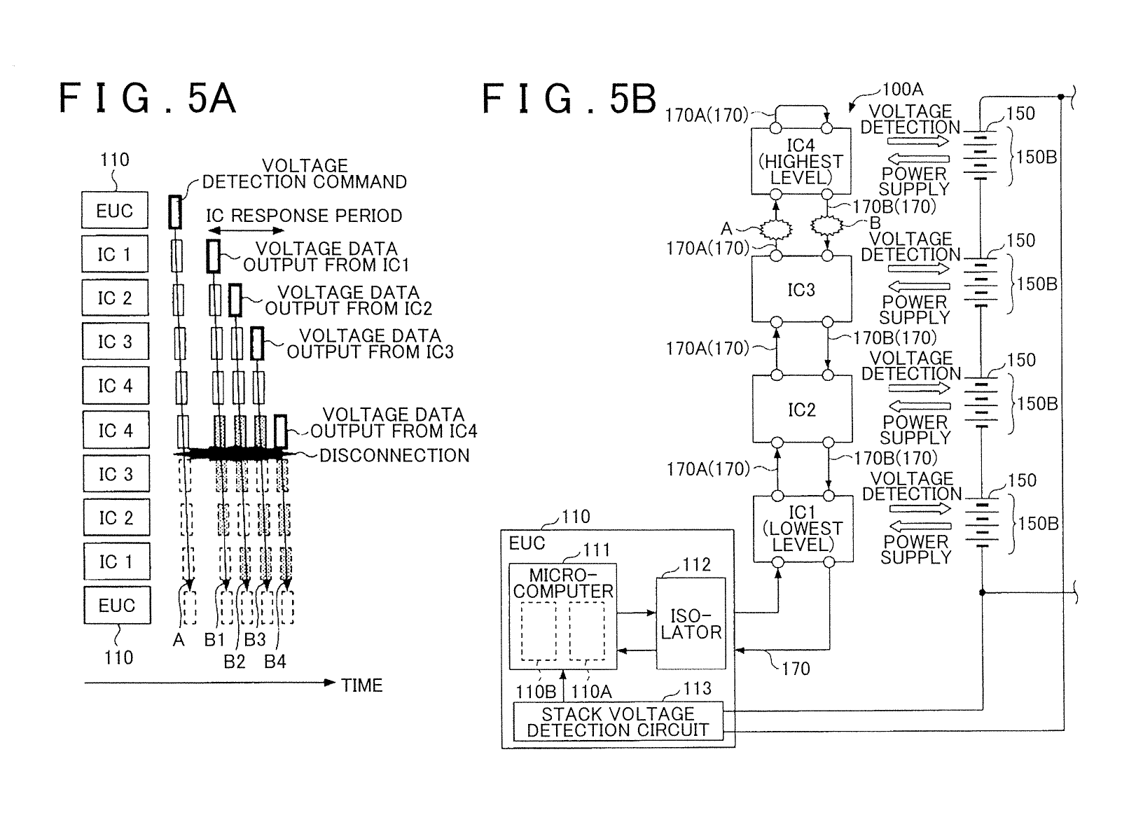

Next, referring to FIG. 5, the following describes how data is transferred by the data transfer method, shown in FIG. 3, when a disconnection is generated on the backward path signal line 170B (see FIG. 2) between IC4 and IC3.

FIG. 5 is a diagram showing the data transfer status when a disconnection is generated on the signal line 170 (see FIG. 2) between IC4 and IC3.

In FIG. 5A, the voltage detection command is transferred via the signal line 170 from the ECU 110 to IC1-IC4 along arrow A from top to bottom of the figure.

This voltage detection command causes each of IC1-IC3 to sequentially transfer its voltage data to the ICs on the side higher than its level via the forward path signal line 170A. IC4 outputs voltage data on IC4 to the backward path signal line 170B to transfer its voltage data to IC3.

At this time, if a disconnection is generated on the backward path signal line 170B (see FIG. 2) between IC4 and IC3 as shown in FIG. 5A, data cannot be transferred from IC4 to IC3 on the backward path signal line 170B. Therefore, the voltage detection command, indicated by arrow A, and voltage data on IC1-IC4, indicated by arrows B1-B4, cannot be transferred from IC4 to IC3 on the backward path signal line 170B.

In FIG. 5A, the voltage detection command and the voltage data, both of which are indicated by a broken line, indicate those that cannot be transferred due to the disconnection between IC4 and IC3 on the backward path signal line 170B.

Such a disconnection, if generated, prevents the voltage detection command from returning to ECU 110. The disconnection also prevents voltage data on IC1-IC4 from reaching the ECU 110.

When there is no disconnection on the signal line 170, the time from the moment the ECU 110 sends the voltage detection command to IC1-IC4 to the moment the ECU 110 receives the voltage detection command depends on the path length of the signal line 170 and the processing speed of IC1-IC4. During this period, the voltage detection command is transferred on the forward path signal line 170A through IC1-IC4 and then on the backward path signal line 170B.

Therefore, in the first embodiment, if the voltage detection command is not received within a predetermined period from the moment it is sent to IC1-IC4, the ECU 110 determines that a disconnection is generated on the signal line 170.

When it is determined that a disconnection is generated on the signal line 170, the ECU 110 sends the test mode command to IC1-IC4 via the signal line 170 to place IC1-IC4 in the test mode.

When an IC of IC1-IC4, which receives the test mode command from the ECU 110 via the signal line 170 and wants to return a response to a request from the ECU 110 during the test mode, it returns the response via the backward path signal line 170B. That is, in this case, instead of outputting the response to the ICs on the side higher its level via the forward path signal line 170A, the IC that receives the test mode command internally switches the transfer destination and outputs the response to the ICs on the side lower level its level via the backward path signal line 170B.

When two or more ICs of IC1-IC4 receive the test mode command from the ECU 110 via the signal line 170, each of those ICs that receives the test mode command returns a response via the backward path signal line 170B after the wait time, which differs among ICs, has elapsed.

The ECU 110 identifies a disconnection position on the signal line 170 based on the responses received from ICs (ICs of IC1-IC4 on the side lower than the disconnection position) in the test mode. The ECU 110 can identify between which ICs of IC1-IC4 on at least one of the forward path signal line 170A and the backward path signal line 170B a disconnection is generated. The reasons is that, also when a disconnection is generated on the forward path signal line 170A, the voltage detection command does not return to, nor does the voltage data on IC1-IC4 reach, the ECU 110 as when a disconnection is generated on the backward path signal line 170B as shown in FIG. 5A. When a disconnection is generated on the forward path signal line 170A, the ECU 110 also sends the test mode command, which places IC1-IC4 in the test mode, to IC1-IC4 via the signal line 170.

After identifying between which ICs of IC1 to IC4 on at least one of the forward path signal line 170A and the backward path signal line 170B a disconnection is generated, the ECU 110 sends the recovery mode command that places the ICs, which are on the side lower than the disconnection position, in the recovery mode. This recovery mode command includes the information indicating the disconnection position (information indicating between which two ICs the disconnection is generated on the signal line 170).

In the recovery mode, based on the voltage data sent from the ICs on the side lower than the disconnection position and the stack voltage detected by the stack voltage detection circuit 113 (see FIG. 2), the ECU 110 determines between which ICs of C1-IC4 on one of the forward path signal line 170A and the backward path signal line 170B the disconnection is generated.

That is, as shown in FIG. 5B, the ECU 110 can determine disconnection A, generated on the forward path signal line 170A between IC3 and IC4, and disconnection B, generated on the backward path signal line 170B between IC3 and IC4.

FIG. 5A shows how data is transferred when a disconnection is generated in the data transfer method shown in FIG. 3. This data transfer applies also to the data transfer method shown in FIG. 4. That is, when a disconnection is generated in the data transfer method shown in FIG. 4, the voltage detection command does not return to, nor does the voltage data on IC1-IC4 reach, the ECU 110. Therefore, when a disconnection is generated in the data transfer method shown in FIG. 4, the ECU 110 also sends the test mode command to IC1-IC4 via the signal line 170 and, after that, sends the recovery mode command to set the recovery mode in the same manner as when a disconnection is generated in the data transfer method shown in FIG. 3.

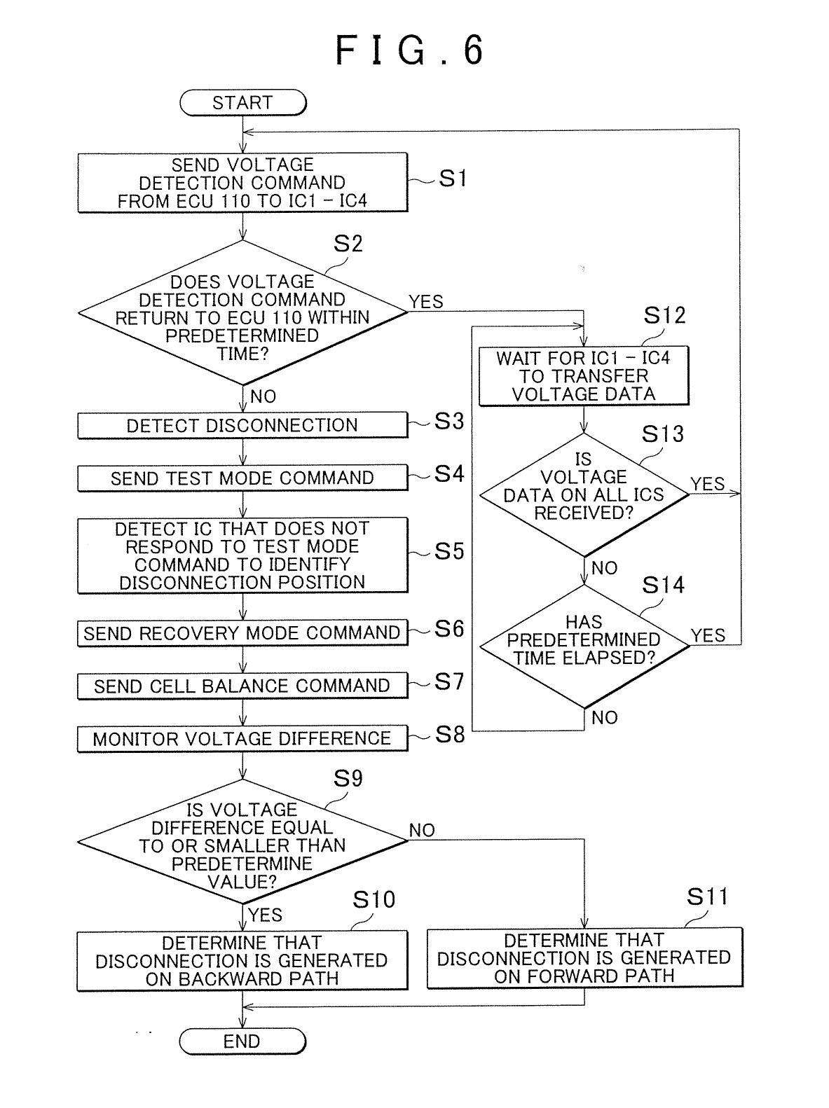

Next, the control processing performed by the ECU 110 is described with reference to FIG. 6.

FIG. 6 is a flowchart showing the processing content of the ECU 110 when a disconnection is generated on the signal line 170 of the battery monitoring device 100A in the first embodiment.

The ECU 110 starts the processing (start). The processing is started, for example, when the ignition of a vehicle, on which the battery monitoring device 100A and the battery unit 100 are mounted, is turned on. This processing may be performed also when the ignition of a vehicle is off.

The ECU 110 sends the voltage detection command to IC1-IC4 (step S1). The processing in step S1 is the processing in which the ECU 110 sends the voltage detection command to IC1-IC4.

Here, assume that IC1-IC4 are distinguished by identifiers and that the ECU 110 holds the identifies of IC1-IC4. When sending voltage data to the ECU 110, each of IC1-IC4 sends its voltage data to the ECU 110 with its identifier associated with the voltage data.

When the voltage detection command is received from the ECU 110, each of IC1-IC4 transfers the voltage detection command to the ICs on the side higher than its level and, at the same time, generates voltage data.

Therefore, when the voltage detection command is sent from the ECU 110 to IC1-IC4 during the processing in step S1, IC1-IC4 sequentially receive the voltage detection command.

As a result, IC1-IC4, which receive the voltage detection command, sequentially send voltage data to the ECU 110.

Next, the ECU 110 determines whether the voltage detection command, which circulates around the signal line 170, returns to it within a predetermined time (step S2). The ECU 110 performs this step because, if there is no abnormality on the signal line 170, the voltage detection command should be transferred to IC1-IC4 via the forward path signal line 170A and then, via the backward path signal line 170B, return to the ECU 110.

That is, by determining in step S2 whether the voltage detection command returns to it, the ECU 110 can determine whether there is a disconnection on the signal line 170.

If the voltage detection command, which circulates around the signal line 170, does not return to it within a predetermined time (S2: NO), the ECU 110 determines that a disconnection is generated on the signal line 170 (step S3). At this time, though it is determined that there is a disconnection somewhere on the signal line 170, it cannot be determined where (between which two ICs) the disconnection is generated.

Next, the ECU 110 sends the test mode command to IC1-IC4 (step S4). The test mode command is a mode change command that places ICs, which are ICs included in IC1-IC4 and are on the side lower than the disconnection position, in the test mode.

The mode of an IC, which receives the test mode command, is changed to the test mode in which a test response is returned. In the test mode, an IC sends a response to the ECU 110 via the backward path signal line 170B. This response may be a command that includes the identifier identifying an IC (one of IC1-IC4).

Next, the ECU 110 detects an IC that does not respond to the test mode command to identify the disconnection position (step S5).

For example, if a response is returned from IC1-IC3 but not from IC4, the ECU 110 determines that a disconnection is generated at least somewhere on the forward path signal line 170A or the backward path signal line 170B between IC3 and IC4.

When the disconnection is generated on the forward path signal line 170A between IC3 and IC4, the test mode command is not transferred to IC4. When the disconnection is generated on the backward path signal line 170B between IC3 and IC4, the test mode command is transferred to IC4 but the voltage data on IC4 is not transferred to IC3 and, as a result, is not transferred to the ECU 110.

Next, the ECU 110 sends the recovery mode command to IC1-IC3 (step S6). The recovery mode is a mode in which the voltage control processing is continued for the ICs, which are on the side lower than the disconnection position, with the IC nearest to the disconnection position as the highest level IC. The recovery mode command is a command sent to an IC to implement the recovery mode.

The recovery mode command includes information indicating the disconnection position (information indicating between which two ICs the disconnection is generated on the signal line 170). That is, when a disconnection is generated between IC3 and IC4, the recovery mode command includes the information indicating that the disconnection is generated between IC3 and IC4. The information, indicating a disconnection position and included in the recovery mode command, is the information indicating between which two ICs on the signal line 170 a disconnection is generated without distinguishing between the forward path signal line 170A and the backward path signal line 170B.

When a disconnection is generated on the forward path signal line 170A between IC3 and IC4, the recovery mode command, if issued, allows IC3 to recognize itself as the highest level IC and send a response to the ECU 110. That is, IC3 sends its voltage data to the ECU 110 without having to wait for voltage data to be sent from IC4.

IC4 continues the voltage averaging processing for its four corresponding cells 150 without sending voltage data.

The ECU 110 sends the cell balance command to IC1-IC4 to cause them to perform the cell balance processing (step S7). The cell balance processing refers to the processing in which each of IC1-IC4 selects the cell 150 the output voltage of which is the lowest among the four cells 150 corresponding to the IC and, to balance the voltage among the four cells corresponding to the IC, discharges the remaining three cells 150 so that the output voltages of all four cells 150 are set to the output voltage of the selected cell 150.

When the cell balance command is received from the ECU 110, each of IC1-IC4 performs the cell balance processing in which, in order to set the output voltages of its four corresponding cells 150 to the lowest output voltage of the four cells 150 of the

IC, the three remaining cells 150 are discharged.

Next, the ECU 110 monitors the voltage difference between the stack voltage, detected by the stack voltage detection circuit 113, and the total of the output voltages indicated by the voltage data sent from the ICs on the side lower than the disconnection generation position (step S8). That is, the ECU 110 monitors the difference between the stack voltage detected by the stack voltage detection circuit 113 and the total of the voltages indicated by the voltage data received via the signal line 170. Note that the voltage data in this embodiment indicates the average of the output voltages of the four cells 150 corresponding to one IC. Therefore, the ECU 110 monitors the voltage difference obtained by subtracting the total of the voltages, which is calculated by adding up the four times the average voltage indicated by each of all voltage data sent from all ICs on the side lower than the disconnection generation position, from the stack voltage.

Next, the ECU 110 determines whether the voltage difference is equal to or smaller than a predetermined value (step S9). The voltage value indicated by the voltage difference is the total value of the output voltages of the cells 150 corresponding to the ICs on the side higher than the disconnection position.

At this time, when the disconnection position is on the forward path signal line 170A, neither the cell balance command is transferred to the ICs on the side higher than the disconnection position nor do the ICs on the side higher than the disconnection position perform the cell balance processing. Therefore, the cell balance command, if sent from the ECU 110, hardly varies the output voltage of the block 150B of the cells 150 corresponding to the ICs on the side higher than the disconnection position.

On the other hand, when the disconnection position is on the backward path signal line 170B, the cell balance command is transferred to the ICs on the side higher than the disconnection position and, thus, the ICs on the side higher than the disconnection position also perform the cell balance processing. Therefore, when the ECU 110 sends the cell balance command, the cell balance processing is performed that decreases the output voltage of the block 150B of the cells 150 corresponding the ICs on the side higher than the disconnection position.

Therefore, the predetermined voltage value used for the determination in step S9 may be calculated in advance by experiment and stored in the memory 110B of the ECU 110 for use in the determination in step S9.

If the voltage difference is decreased by the predetermined voltage value or more in step S9 (S9: YES), the ECU 110 determines that a disconnection is generated on the backward path signal line 170B. Therefore, if the result in step S9 is YES when it is already determined in step S5 that a disconnection is generated between IC3 and IC4, the ECU 110 identifies that a disconnection is generated on the backward path signal line 170B between IC3 and IC4.

On the other hand, if the voltage difference is not decreased by the predetermined voltage value or more in step S9 (S9: NO), the ECU 110 determines that a disconnection is generated on the forward path signal line 170A. Therefore, if the result in step S9 is NO when it is determined in step S5 that a disconnection is generated between IC3 and IC4, the ECU 110 identifies that a disconnection is generated on the forward path signal line 170A between IC3 and IC4.

When the processing in step S10 or S11 is terminated, the ECU 110 terminates the sequence of processing (End).

The ECU 110 may be configured to start (Start) the sequence of processing again after a predetermined period elapses after the termination of the sequence of processing.

If it is determined in step S2 that the voltage detection command that has circulated around the signal line 170 returns to the ECU 110 within a predetermined time (S2: YES), the ECU 110 waits for IC1-IC4 to transfer voltage data (step S12).

Next, the ECU 110 determines whether voltage data is received from all ICs (step S13). The ECU 110 compares the identifier included in the received voltage data with the identifier of each IC held in the ECU 110 to determine whether voltage data on all ICs is acquired.

If it is determined that voltage data on all ICs is not yet acquired (S13: NO), the ECU 110 proceeds to step S14 in the flow.

The ECU 110 determines whether a predetermined time has elapsed (step S14). This predetermined time may be set to an average time required for IC1-IC4 to generate voltage data and transfer the generated voltage data to the ECU 110. The predetermined time may be set to an appropriate time according to the use of the battery monitoring device 100A.

If the predetermined time has not yet elapsed (S14: NO), the ECU 110 returns to step S12 in the flow. In that step, the ECU 110 continues to wait for IC1-IC4 to transfer voltage data.

If the predetermined time has elapsed (S14: YES), the ECU 110 returns control to step S1 in the flow. If voltage data on IC1-IC4 is not acquired in the predetermined time, the ECU 110 repeats the flow beginning in step S1.

If it is determined in step S13 that voltage data on all ICs is received, the ECU 110 returns control to step S1 in the flow. The ECU 110 repeats the flow beginning in step S1 to repeatedly monitor IC1-IC4.

The ECU 110 performs the voltage control processing as described above.

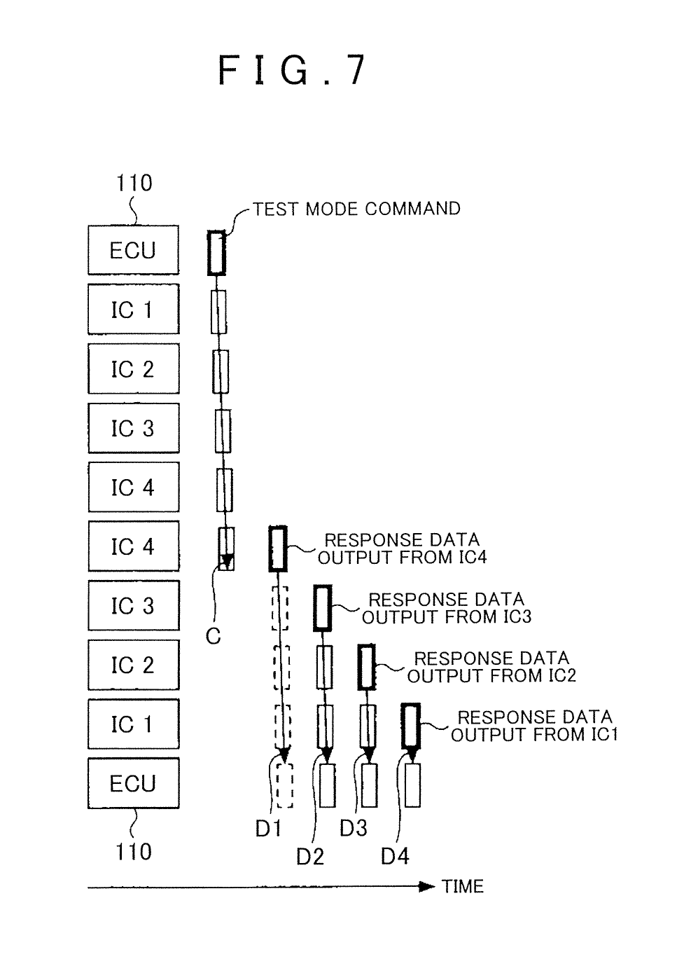

Next, data transfer in the test mode and the recovery mode is described below with reference to FIG. 7.

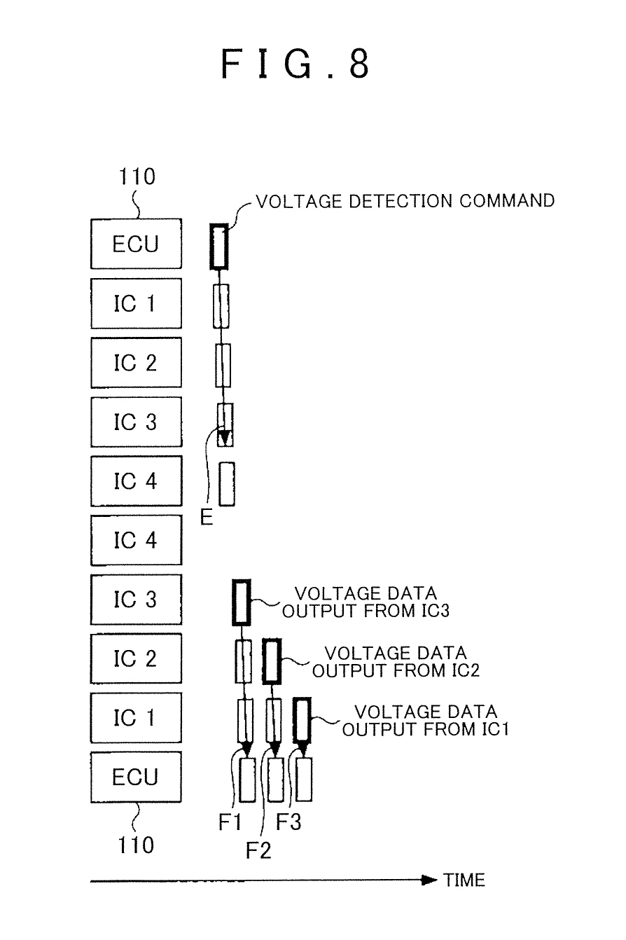

FIG. 7 and FIG. 8 are diagrams showing the data transfer path in the test mode and in the recovery mode of the battery monitoring device 100A in the first embodiment. FIG. 7 shows the data transfer path in the test mode, and FIG. 8 shows the data transfer path in the recovery mode.

In FIG. 7 and FIG. 8, assume that a disconnection is generated on the backward path signal line 170B (see FIG. 2) between IC3 and IC4.

When sent from the ECU 110 as shown in FIG. 7, the test mode command is transferred from IC1 to IC4 on the forward path signal line 170A (see FIG. 2) as indicated by arrow C and is looped back at IC4.

In response to the test mode command, IC1-IC4 sequentially send response data to the ECU 110 in the direction from the high-level side to the low-level side. The response data includes the identifier of each IC. The interval of time at which IC1-IC4 output response data in this order is set longer than the interval of time at which IC1-IC4 output voltage data shown in FIG. 3.

In FIG. 7, response data output from each IC in the test mode is indicated by a thick-bordered box.

The interval at which the response data shown in FIG. 7 is output (the horizontal interval at which the response data, each indicated by a thick-bordered box, is generated in FIG. 7) is set wider (longer) than the interval at which voltage data is output in FIG. 3. This interval is set wider in this manner to prevent the communication of response data, which is sent from the ICs to the ECU 110 in the order of IC4 to IC1, from being duplicated.

The time interval at which response data is output in the order of IC4 to IC1 in this manner is set in IC1-IC4 in advance.

Setting the time interval in this manner allows response data to be output from IC4, IC3, IC2, and IC1 in this order.

However, in the case shown in FIG. 7, a disconnection is generated on the backward path signal line 170B (see FIG. 2) between IC3 and IC4.

This disconnection prevents response data, sent from IC4, from being transferred from IC3 to the ECU 110. To show this condition, the path along which, and the time at which, the response data sent from IC4 would normally be transferred to the ECU 110 is indicated by broken lines in FIG. 7. If a disconnection were not generated, the response data sent from IC4 to the ECU 110 would be transferred to the ECU 110 along arrow D1.

The response data sent from IC3 to the ECU 110 is transferred to the ECU 110 via the backward path signal line 170B. Because this transfer is not affected by the disconnection, the response data from IC3 reaches the ECU 110 through IC2 and IC1 as indicated by arrow D2.

If there is no disconnection, the response data from IC3 is transferred to the ECU 110 at a time that does not coincide with a time at which the response data from IC4 is normally transferred to the ECU 110.

Similarly, the response data sent from IC2 to the ECU 110 is transferred to the ECU 110 via the backward path signal line 170B. Because this transfer is not affected by the disconnection, the response data from IC2 reaches the ECU 110 through IC1 as indicated by arrow D3.

The response data from IC2 is transferred to the ECU 110 at a time that does not coincide with a time at which the response data from IC3 is transferred to the ECU 110.

Similarly, the response data sent from IC1 to the ECU 110 is transferred to the ECU 110 via the backward path signal line 170B. Because this transfer is not affected by the disconnection, the response data from IC1 reaches the ECU 110 as indicated by arrow D4.

The response data from IC1 is transferred to the ECU 110 at a time that does not coincide with a time at which the response data from IC2 is transferred to the ECU 110.

As described above, by sending the test mode command to IC1-IC4 and receiving response data from IC1-IC3, the ECU 110 can determine that a disconnection is generated on the signal line (forward path signal line 170A or backward path signal line 170B) between IC3 and IC4. That is, the ECU 110 can determine the disconnection position.

After determining the disconnection position, the ECU 110 sends the recovery mode command to change the mode of IC1-IC3 to the recovery mode. This processing for identifying the disconnection position corresponds to the processing in step S5 shown in FIG. 6.

The ECU 110 sends the recovery mode command to IC1-IC3. The recovery mode command includes the information indicating a disconnection position. In the above example, the recovery mode command includes the information indicating that a disconnection is generated on the signal line 170 between IC3 and IC4. The information indicating the disconnection position is stored, for example, in a several-bit area in the recovery mode command.

IC1-IC3 receive the recovery mode command and have the mode changed to the recovery mode. Based on the recovery mode command, IC3 recognizes that it is the highest-level IC because the disconnection is generated between IC3 and IC4.

The recovery mode is performed as shown in FIG. 8. That is, when the ECU 110 sends the voltage detection command to IC1-IC3 as indicated by arrow E, IC1-IC3 send voltage data to the ECU 110 in the order of IC3, IC2, and IC1, as indicated by arrow F1, F2, and F3.

When no disconnection is generated, any of the transfer methods shown in FIG. 3 and FIG. 4 may be used. Note that however an IC that operates in the recovery mode outputs voltage data to the backward path signal line 170B. That is, in the recovery mode, an IC sends voltage data to the ECU 110 via the backward path signal line 170B.

After the mode is set to the recovery mode, the ECU 110 performs the processing from step S7 to step S10 or to step S11 shown in FIG. 6. After the cell balance processing is performed, the ECU 110 monitors the voltage difference and, according to the degree of the voltage difference reduction, determines on which signal line, forward path signal line 170A or backward path signal line 170B, the disconnection is generated.

As described above, upon detecting that a disconnection is generated on the signal line 170, the battery monitoring device 100A in the first embodiment identifies the disconnection position in the test mode. After identifying the disconnection position, the battery monitoring device 100A enters the recovery mode and performs the voltage control processing using only the ICs on the side lower than the disconnection position (on the side nearer to the ECU 110).

After performing the cell balance processing, the ECU 110 monitors the voltage difference to determine on which signal line, forward path signal line 170A or backward path signal line 170B, the disconnection is generated.

As described above, the first embodiment provides the battery monitoring device 100A and the battery unit 100 that can determine on which communication line path, forward path or backward path, a disconnection is generated. In other words, the first embodiment provides the battery monitoring device 100A and the battery unit 100 that can determine on which daisy chain path, forward path or backward path, a disconnection is generated.

By performing the cell balance processing in step S7 when monitoring the voltage difference, the voltages of the cells 150 corresponding to the ICs on the side higher than the disconnection position can be decreased relatively sooner when the disconnection is generated on the backward path. Therefore, the cell balance processing, if performed, makes it possible to quickly determine on which path the disconnection is generated.

However, the cell balance processing need not always be performed. That is, the ECU 110 can determine on which communication line path, forward path or backward path, a disconnection is generated without having to perform the cell balance processing.

The reason is as follows. After a disconnection is generated, the ECU 110 still continues to transfer the voltage detection command to IC1-IC4. When a disconnection is generated on the backward path signal line 170B, the voltage detection command is transferred also to the ICs on the side higher than the disconnection position and, in response to the command, the ICs on the side higher than the disconnection position perform the processing to transfer voltage data to the ECU 110. Therefore, the output voltage of the cells 150 corresponding to the ICs on the side higher than the disconnection position is decreased, and the stack voltage detected by the stack voltage detection circuit 113 is decreased.

On the other hand, when a disconnection is generated on the forward path signal line 170A, neither the voltage detection command is transferred to the ICs on the side higher than the disconnection position nor do the ICs on the side higher than the disconnection position perform the processing. Therefore, the output voltage of the cells 150 corresponding to the ICs on the side higher than the disconnection position is not decreased, and the stack voltage detected by the stack voltage detection circuit 113 is not practically changed.

Therefore, when the cell balance processing in step S7 is not performed, step S6 is followed immediately by step S8 in which the voltage difference is monitored to determine on which signal line, forward path signal line 170A or backward path signal line 170B, the disconnection is generated.

Although each of the stacks 120 and 130 includes four IC chips 160 (IC1-IC4) in the above mode, one stack (120, 130) may include more IC chips 160. Similarly, one stack (120, 130) may include three or less IC chips 160.

### Second Embodiment

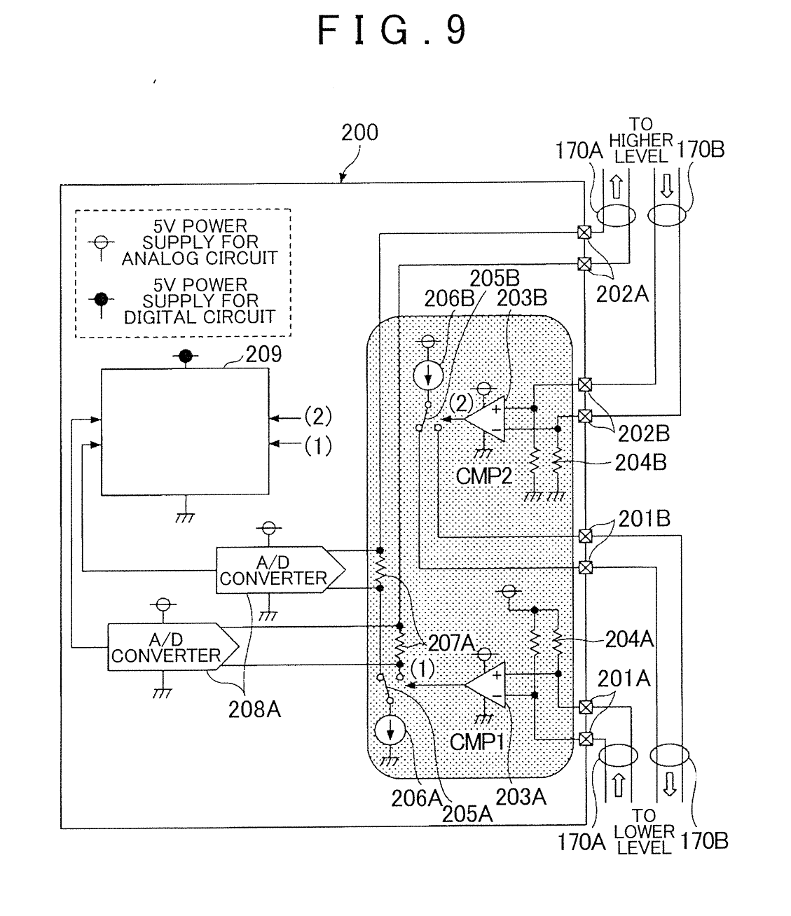

FIG. 9 is a diagram showing a communication circuit 200 of a battery monitoring device in a second embodiment. The battery monitoring device in the second embodiment differs from the battery monitoring device 100A in the first embodiment in the determination method that is used to determine on which signal line, forward path signal line 170A or backward path signal line 170B, a disconnection is generated. Because the other configuration is similar to the configuration of the battery monitoring device 100A (see FIG. 2) in the first embodiment, the same reference numeral is given to the same component and the detailed description is omitted.

The communication circuit 200 is inserted between the signal lines 170A and 170B between IC1 and IC2 shown in FIG. 2. The communication circuit 200 is inserted between the signal lines 170A and 170B also between IC2 and IC3 and between IC3 and IC4. Both signal lines 170A and 170B are used to transfer a differential signal and, in the figure, a pair of signal lines 170A and a pair of signal lines 170B are shown.

The communication circuit 200 includes a pair of input terminals 201A, a pair of output terminals 201B, a pair of output terminals 202A, a pair of input terminals 202B, comparators 203A and 203B, a pair of resistors 204A, a pair of resistors 204B, switches 205A and 205B, current sources 206A and 206B, a pair of resistors 207A, a pair of A/D converters 208A, and a logic circuit 209.

Of these components, a component with the subscript A is a component related to the forward path signal line 170A and a component with the subscript B is a component related to the backward path signal line 170B. A component with no subscript (logic circuit 209) is a component related to both forward path signal line 170A and backward path signal line 170B.

To the pair of input terminals 201A, a signal is input from an IC on the lower level side or from the ECU 110. In the communication circuit 200, the pair of input terminals 201A is connected to the inverted input terminal and the non-inverted input terminal of the comparator 203A and to the pair of resistors 204A.

The comparator 203A compares the signal input to the inverted input terminal and the signal input to the non-inverted input terminal to drive the switch 205A with the signal (1) indicating the comparison result. The signal (1) is input also to the logic circuit 209. The signal (1) represents the differential signal transferred by the pair of signal lines 170A.

The switch 205A selects one of the resistors 207A of the pair as the destination to which the current source 206A is connected. The switch 205A is driven by the signal (1) output by the comparator 203A.

The current source 206A is connected in such a manner that the current is extracted from the resistor 207A connected to the switch 205A.

The pair of A/D converters 208A converts the end-to-end voltage of the pair of resistors 207A respectively to a digital value and sends the converted digital value to the logic circuit 209.

The logic circuit 209 operates in synchronization with the signal (1), output by the comparator 203A, to monitor the voltage value received from the pair of A/D converters 208A.

To the pair of input terminals 202B, a signal is input from an IC on the higher level side. In the communication circuit 200, the pair of input terminals 202B is connected to the inverted input terminal and the non-inverted input terminal of the comparator 203B and to the pair of resistors 204B.

The comparator 203B compares the signal input to the inverted input terminal and the signal input to the non-inverted input terminal to drive the switch 205B with the signal (2) indicating the comparison result. The signal (2) is input also to the logic circuit 209. The signal (2) represents the differential signal transferred by the pair of signal lines 170B.

The switch 205B selects one of the output terminals 201B of the pair as the destination to which the current source 206B is connected. The switch 205B is driven by the signal (2) output by the comparator 203B.

The current source 206B is connected in such a manner that the current is supplied to the pair of output terminals 201B connected to the switch 205B.

When a signal is transferred from an IC on the lower level side or the ECU 110 to an IC on the higher level side in the communication circuit 200 such as the one described above, the current source 206A extracts the current from the pair of signal lines 170A on the forward path, connected to the pair of output terminals 202A, through the pair of resistors 207A and the switch 205A.

That is, in this embodiment, the ECU 110 first performs the processing to step S5 to identify whether a disconnection is generated between IC1 and IC2, between IC2 and IC3, or between IC3 and IC4 shown in FIG. 2 as in the battery monitoring device 100A in the first embodiment. After that, based on whether the logic circuit 209 in the communication circuit 200, which corresponds to the position where the disconnection is generated, detects a variation in the voltage, the ECU 110 determines on which path of the signal line 170, forward path or backward path, the disconnection is generated. More specifically, when the corresponding logic circuit 209 detects a variation in the voltage, the ECU 110 determines that no disconnection is generated on the forward path signal line 170A. In other words, the ECU 110 determines that the disconnection is generated on the backward path signal line 170B.

On the other hand, the ECU 110 performs the processing to step S5 and identifies a disconnection position and, after that, when the logic circuit 209 in the corresponding communication circuit 200 does not detect a variation in the voltage, the ECU 110 determines that the disconnection is generated on the forward path signal line 170A. Any method may be used to transmit a result, detected by the corresponding logic circuit 209, to the ECU 110.

As described above, the ECU 110 can determine on which signal line, forward path signal line 170A or backward path signal line 170B, a disconnection is generated.

In this manner, the second embodiment provides a battery monitoring device and a battery unit that can determine on which communication line path, forward path or backward path, a disconnection is generated.

### Third Embodiment

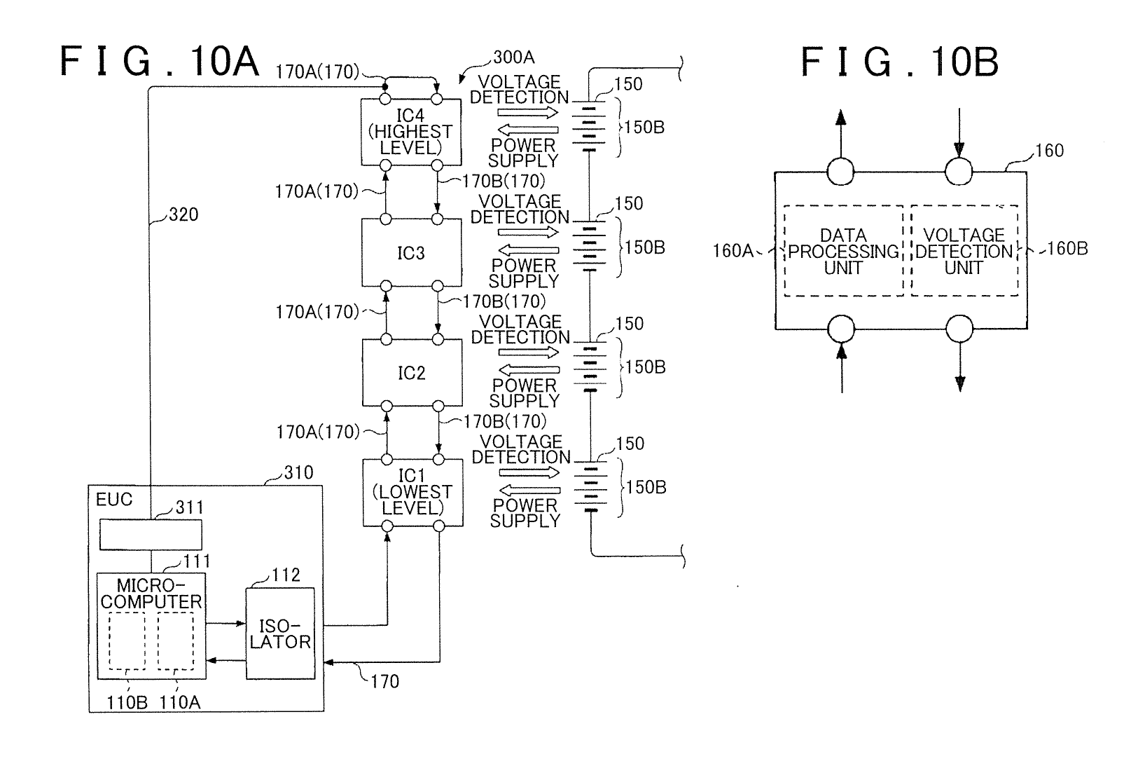

FIG. 10 is a diagram showing a battery monitoring device 300A in a third embodiment. The battery monitoring device 300A in the third embodiment shown in FIG. 10A has a configuration similar to that of the battery monitoring device 100A in the first embodiment except that the stack voltage detection circuit 113 is removed from the battery monitoring device 100A and a capacitor 311 is added to an ECU 310. Because the other configuration is similar to the configuration of the battery monitoring device 100A in the first embodiment, the same reference numeral is given to the same component and the detailed description is omitted.

The ECU 310 includes the microcomputer 111, isolator 112, and capacitor 311. One end of the capacitor 311 is connected to the point, at which the forward path signal line 170A is looped back at IC4, by a signal line 320, and the other end is connected to the microcomputer 111. That is, the signal line 320 connects the ECU 310 to IC4 that is the IC farthest from the ECU 310. The IC farthest from the ECU 310 is the highest level IC on the daisy chain, which corresponds to IC4 in this example.

The capacitor 311 is provided to send to the microcomputer 111 only the AC components of the signal transmitted from the point, at which the forward path signal line 170A is looped back at IC4, via the signal line 320.

Therefore, as in the battery monitoring device 100A in the first embodiment, when the ECU 310 performs the processing to step S5 and identifies a disconnection position and, after that, the ECU 310 receives the signal via the capacitor 311, the ECU 310 determines that no disconnection is generated on the forward path signal line 170A. This is because, in this case, the signal transferred from the ECU 310 to IC1-IC4 via the forward path signal line 170A reaches the highest level IC4. In this case, the ECU 310 determines that the disconnection is generated on the backward path signal line 170B.

On the other hand, when the ECU 310 performs the processing to step S5 and identifies a disconnection position and, after that, the ECU 310 does not receive the signal via the capacitor 311, the ECU 310 determines that the disconnection is generated on the forward path signal line 170A. This is because, in this case, the signal transferred from the ECU 310 to IC1-IC4 via the forward path signal line 170A does not reach the highest level IC4.

It is also possible to determine on which signal line, forward path signal line 170A or backward path signal line 170B, a disconnection is generated as described above.

In this manner, the third embodiment provides a battery monitoring device 300A and a battery unit that can determine on which communication line path, forward path or backward path, a disconnection is generated.

Although the battery monitoring device and the battery unit in the exemplary embodiments of the present invention have been described above, it is to be understood that the present invention is not limited to the specific embodiments that are disclosed but various modifications and changes are possible without departing from the claims.

What is claimed is:

1. A battery monitoring device comprising:
a first control unit arranged outside a plurality of battery stacks each of which includes battery cells;
a plurality of second control units arranged in each of the plurality of battery stacks to detect an output voltage, of the battery cells and then output voltage data indicating the output voltage;
a signal line that connects the plurality of second control units and the first control unit in a daisy chain mode; and
a stack voltage detection unit that detects a stack voltage that is a total voltage of the plurality of battery cells included in the battery stacks wherein
each of the second control units receives a data signal sent from the first control unit via the signal line and, in response to the data signal, sends a response signal and
the first control unit determines that a disconnection is generated on the signal line when the response signal is not received via the signal line within a predetermined period after the data signal is sent to the plurality of second control units via the signal line and, in addition, determines on which path of the signal line, a forward path or a backward path, the disconnection is generated based on a difference between the stack voltage and a total of output voltages, the stack voltage detected by the stack voltage detection unit, the total of output voltages indicated by the voltage data received from the second control units via the signal line.

2. The battery monitoring device according to claim 1, wherein
when it is determined that a disconnection is generated on the signal line, the first control unit sends a command, which causes the plurality of second control units to perform cell balance processing, via the signal line.

3. A battery monitoring device comprising:
a first control unit arranged outside a plurality of battery stacks each of which includes battery cells;
a plurality of second control units arranged in each of the plurality of battery stacks to detect an output voltage of the battery cells and then output voltage data indicating the detected voltage;
a signal line that connects the plurality of second control units and the first control unit in a daisy chain mode; and
a current detection unit provided between each two of the plurality of second control units in a forward path section of the signal line wherein
each of the second control units receives a data signal sent from the first control unit via the signal line and, in response to the data signal, sends a response signal and
the first control unit determines that a disconnection is generated on the signal line when no response is received from the plurality of second control units via the signal line within a predetermined period after the data signal is sent to the plurality of second control units via the signal line and, in addition, determines on which path of the signal line, a forward path or a backward path, the disconnection is generated based on a detection result of the current detection unit.

4. A battery monitoring device comprising:
a first control unit arranged outside a plurality of battery stacks each of which includes battery cells;
a plurality of second control units arranged in each of the plurality of battery stacks to detect an output voltage of the battery cells and then output voltage data indicating the output voltage;
a signal line that connects the plurality of second control units and the first control unit in a daisy chain mode; and
a communication line that connects a second control unit farthest from the first control unit and the first control unit wherein
each of the second control units receives a data signal sent from the first control unit via the signal line and, in response to the data signal, sends a response signal and
the first control unit determines that a disconnection is generated on the signal line when no response is received from the plurality of second control units via the signal line within a predetermined period after the data signal is sent to the plurality of second control units via the signal line and at the same time and
the first control unit determines that the disconnection is generated on a backward path of the signal line when sending data is received from the second control unit farthest from the first control unit via the communication line and determines that the disconnection is generated on a forward path of the signal line when sending data is not received from the second control unit via the communication line.

5. The battery monitoring device according to claim 1, wherein
the first control unit sends a test mode command to the plurality of second control units via the signal line when it is determined that a disconnection is generated on the signal line, the test mode command being a command that places the second control units in a test mode.

6. The battery monitoring device according to claim 5, wherein
the second control unit, which is one of the plurality of second control units and receives the test mode command from the first control unit via the signal line, sends a response via a backward path of the signal line when the second control units sends the response in response to a request from the first control unit during a test mode.

7. The battery monitoring device according to claim 6, wherein
when there is a plurality of second control units that is a part of the plurality of second control units and that receives the test mode command from the first control unit via the signal line, the plurality of second control units that receives the test mode command sends the response via the backward path of the signal line after a wait time elapses, the wait time differing among the plurality of second control units.

8. The battery monitoring device according to claim 6, wherein
the first control unit identifies a disconnection position on the signal line based on the response received from the second control units during the test mode.

9. The battery monitoring device according claim 8, wherein
the first control unit sends a recovery mode command after identifying the disconnection position, the recovery mode command being a command that places the second control units in a recovery mode.

10. The battery monitoring device according claim 9 wherein the recovery mode command includes information indicating the disconnection position.

11. A battery unit comprising:
a plurality of battery stacks each of which includes battery cells;
a first control unit arranged outside the plurality of battery stacks;
a plurality of second control units arranged in each of the plurality of battery stacks to detect an output voltage of the battery cells and then output voltage data indicating the output voltage;
a signal line that connects the plurality of second control units and the first control unit in a daisy chain mode; and
a stack voltage detection unit that detects a stack voltage that is a total voltage of the plurality of battery cells included in the battery stacks wherein
each of the second control units receives a data signal sent from the first control unit via the signal line and, in response to the data signal, sends a response signal and
the first control unit determines that a disconnection is generated on the signal line when the response signal is not received via the signal line within a predetermined period after the data signal is sent to the plurality of second control units via the signal line and, in addition, determines on which path of the signal line, a forward path or a backward path, the disconnection is generated based on a difference between the stack voltage and a total of output voltages, the stack voltage detected by the stack voltage detection unit, the total of output voltages indicated by the voltage data received from the second control units via the signal line.

12. A battery unit comprising:
a plurality of battery stacks each of which includes battery cells;
a first control unit arranged outside the plurality of battery stacks;
a plurality of second control units arranged in each of the plurality of battery stacks to detect an output voltage of the battery cells and then output voltage data indicating the detected voltage;
a signal line that connects the plurality of second control units and the first control unit in a daisy chain mode; and
a current detection unit provided between each two of the plurality of second control units in a forward path section of the signal line wherein
each of the second control units receives a data signal sent from the first control unit via the signal line and, in response to the data signal, sends a response signal and
the first control unit determines that a disconnection is generated on the signal line when no response is received from the plurality of second control units via the signal line within a predetermined period after the data signal is sent to the plurality of second control units via the signal line and, in addition, determines on which path of the signal line, a forward path or a backward path, the disconnection is generated based on a detection result of the current detection unit.

13. A battery unit comprising:
a plurality of battery stacks each of which includes battery cells;
a first control unit arranged outside the plurality of battery stacks;
a plurality of second control units arranged in each of the plurality of battery stacks to detect an output voltage of the battery cells and then output voltage data indicating the output voltage;
a signal line that connects the plurality of second control units and the first control unit in a daisy chain mode; and
a communication line that connects a second control unit farthest from the first control unit and the first control unit wherein
each of the second control units receives a data signal sent from the first control unit via the signal line and, in response to the data signal, sends a response signal and
the first control unit determines that a disconnection is generated on the signal line when no response is received from the plurality of second control units via the signal line within a predetermined period after the data signal is sent to the plurality of second control units via the signal line and at the same time
the first control unit determines that the disconnection is generated on a backward path of the signal line when sending data is received from the second control unit farthest from the first control unit via the communication line and determines that the disconnection is generated on a forward path of the signal line when sending data is not received from the second control unit via the communication line.
